(19) United States
(12) Patent Application Publication
(10) Pub. No.: US 2024/0412997 A1
(43) Pub. Date: Dec. 12, 2024

(54) HIGH-PRECISION IN-SITU VERIFICATION AND CORRECTION OF WAFER POSITION AND ORIENTATION FOR ION IMPLANT

(71) Applicant: Applied Materials, Inc., Santa Clara, CA (US)

(72) Inventors: Michael Lee SWEARS, Beverly, MA (US); Santosh Kumar DHULAPATI, Wakefield, MA (US); James R. MCLANE, Beverly, MA (US)

(73) Assignee: Applied Materials, Inc., Santa Clara, CA (US)

(21) Appl. No.: 18/391,503

(22) Filed: Dec. 20, 2023

Related U.S. Application Data
(60) Provisional application No. 63/472,189, filed on Jun. 9, 2023.

(51) Int. Cl. H01L 21/68; H01L 21/67

(52) U.S. Cl. CPC H01L 21/681; H01L 21/67259

(57) ABSTRACT

Disclosed herein are approaches for in-situ verification and correction of a wafer position. In one approach, a method may include illuminating an underside of a platen positioned within a processing chamber, and detecting a perimeter edge of the platen using an imaging device positioned external to the processing chamber, above the platen. The method may further include determining, via a controller, position data for the platen based on the detected perimeter edge of the platen, and positioning a wafer atop the platen based on the position data of the platen, wherein the wafer comprises a positioning notch. The method may further include detecting a position of the wafer and a position of the positioning notch using the imaging device, and comparing the position data of the platen to the detected position of the wafer and comparing the detected position of the positioning notch to an expected notch position

### CROSS-REFERENCE TO RELATED APPLICATIONS

This application claims priority to U.S. provisional patent application Ser. No. 63/472,189, filed Jun. 9, 2023, the entire contents of which is incorporated by reference herein.

### FIELD OF THE DISCLOSURE

The present disclosure relates to semiconductor processing and, more particularly, to approaches for in-situ verification and correction of wafer position atop a platen.

### BACKGROUND OF THE DISCLOSURE

In microchip fabrication, processing chambers are used to accomplish various fabrication steps performed on a wafer. These processing chambers typically include a substantially planar and pedestal upon which the wafer rests during processing. The pedestal may also be known as a platen, stage or susceptor. A lift mechanism provides controlled engagement and disengagement of the wafer with the pedestal surface.

Retention of the wafer to the pedestal while in the chamber is sometimes referred to as chucking. Chucking may be accomplished mechanically such as by clamping at the wafer periphery, or by a vacuum holding force. Chucking may be accomplished electrostatically by an electrostatic chuck. However, either before or during chucking, the wafer may become mispositioned relative to the pedestal.

Therefore, it would be desirable to provide for an apparatus and method for detecting and correcting a variety of wafer process conditions, namely, wafer position.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include illuminating an underside of a platen positioned within a chamber, detecting a perimeter edge of the platen using an imaging device positioned external to the chamber, and determining, via a controller, position data for the platen based on the detected perimeter edge of the platen. The method may further include positioning a wafer atop the platen based on the position data of the platen, wherein the wafer comprises a positioning notch, detecting a position of the wafer and a position of the positioning notch using the imaging device, and comparing the position of the wafer to the position data of the platen and comparing the position of the positioning notch to an expected notch position.

In another aspect, a system for in-situ verification and correction of wafer position may include an illumination device operable to illuminate an underside of a platen, wherein the platen is positioned within a chamber, and wherein the illumination device is positioned external to the chamber. The illumination device may be operable to detect a perimeter edge of the platen, and detect a perimeter edge of a wafer positioned atop the platen and a position of a positioning notch formed in the wafer. The system may further include a controller in communication with the illumination device and the platen, wherein the controller is operable to determine position data for the platen based on the detected perimeter edge of the platen, determine a position of the wafer and a position of the positioning notch, and compare the position of the wafer to the position data of the platen and compare the position of the positioning notch to an expected notch position.

In yet another aspect, a method may include illuminating an underside of a platen positioned within a processing chamber, and detecting a perimeter edge of the platen using an imaging device positioned external to the processing chamber, above the platen. The method may further include determining, via a controller, position data for the platen based on the detected perimeter edge of the platen, and positioning a wafer atop the platen based on the position data of the platen, wherein the wafer comprises a positioning notch. The method may further include detecting a position of the wafer and a position of the positioning notch using the imaging device, and comparing the position of the positioning notch to an expected notch position.

In yet another aspect, a system may include a processor and a memory storing instructions, executable by the processor, to cause illumination of an underside of a platen positioned within a processing chamber and to detect a perimeter edge of the platen using an imaging device positioned external to the processing chamber, above the platen. The memory may further store instructions, executable by the processor, to determine position data for the platen based on the detected perimeter edge of the platen, and to position a wafer atop the platen based on the position data of the platen, wherein the wafer comprises a positioning notch. The memory may further store instructions, executable by the processor, to detect a position of the wafer and a position of the positioning notch using the imaging device, and to compare the position of the positioning notch to an expected notch position.

### BRIEF DESCRIPTION OF THE DRAWINGS

The accompanying drawings illustrate exemplary approaches of the disclosure, including the practical application of the principles thereof, as follows:

FIG. 1 illustrates a top view of an example processing system, according to embodiments of the present disclosure;

FIG. 2 illustrates a side view of a processing chamber of the processing system, according to embodiments of the present disclosure; and

FIG. 3 is a flowchart illustrating a method for determining wafer alignment on a platen, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Systems, processing chambers, and methods in accordance with the present disclosure will now be described more fully hereinafter with reference to the accompanying drawings, where various embodiments are shown. The systems, processing chambers, and methods may be embodied in many different forms and are not to be construed as being limited to the embodiments set forth herein. Instead, these embodiments are provided so the disclosure will be thorough and complete, and will fully convey the scope of the methods to those skilled in the art.

Currently there are few effective methods to verify, in situ on a platen within a processing chamber, that a wafer has been properly positioned and oriented. Most prior art implant systems do not check wafer position after loading the wafer on the platen. Embodiments of the present disclosure address this deficiency by using a camera to detect the position of the platen and then the position of the wafer on the platen. Unlike prior art approaches, which use front/top lighting during imaging, embodiments of the present disclosure use backlighting to more accurately capture the wafer and wafer notch position relative to the platen.

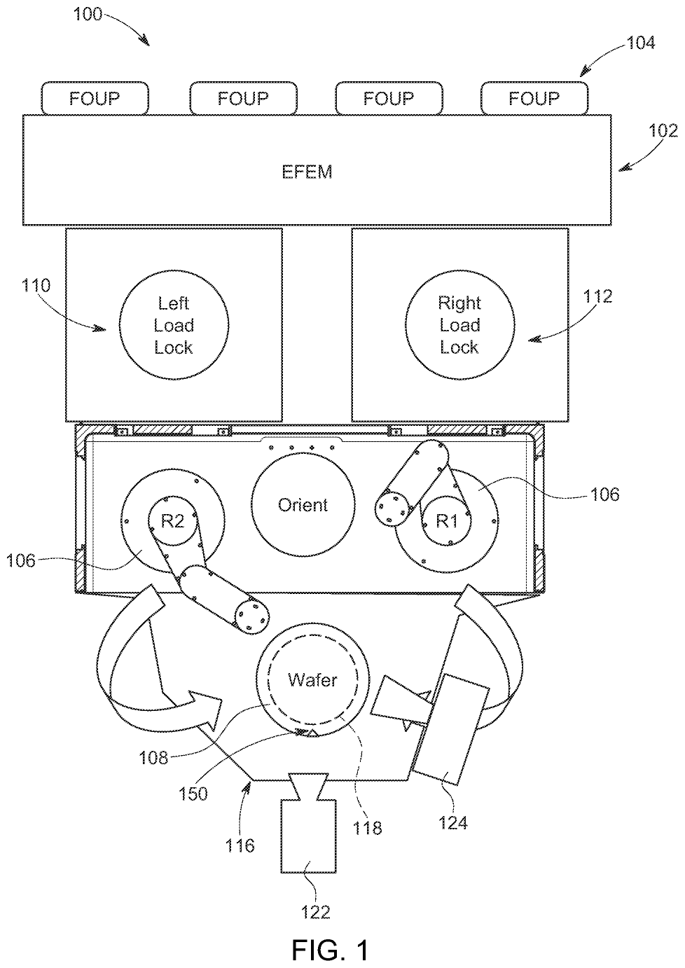

FIG. 1 illustrates a top view of an example semiconductor processing system (hereinafter “system”) 100 according to embodiments of the present disclosure. As shown, the system 100 may include an equipment front end module (EFEM) 102 connected with one or more front opening unified pods (FOUPs) 104, and one or more robots (R1, R2) 106 operable to transfer a wafer 108 between a left load dock 110 and/or a right load dock 112 and a processing chamber 116. The wafer 108 may be positioned atop a platen 118 of a rotating platform (i.e., roplat), which is also located within the processing chamber 116. As will be described in greater detail herein, a position of the platen 118 and of the wafer 108, as well as a position of a wafer alignment mark 150, may be measured and analyzed, in-situ, using a sensor/imaging device 122 and an illumination source 124, both of which are located external to the processing chamber 116. In other embodiments, more than one imaging device 122 and/or illumination source 124 may be present.

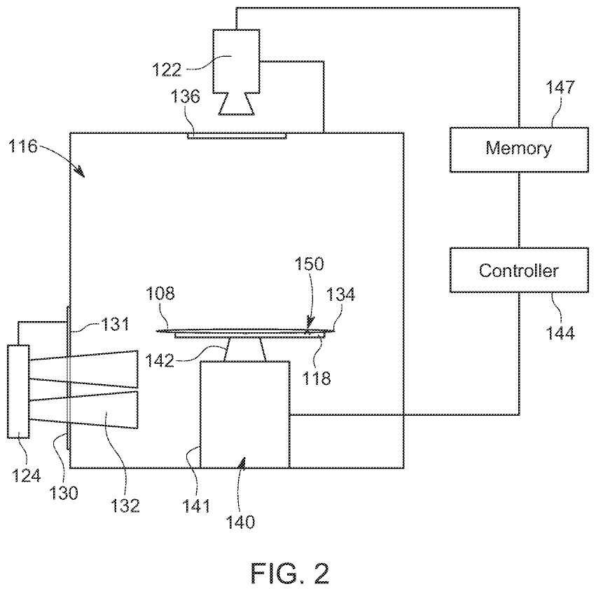

As better demonstrated in FIG. 2, the illumination source 124 may include one or more LEDs coupled to a door 130 of the processing chamber 116, wherein the door 130 includes one or more windows 131 to allow the light 132 to enter the processing chamber 116, beneath the platen 118. In other embodiments, the illumination source 124 may be coupled to a wall of the processing chamber 116 and positioned adjacent the window 131. In some embodiments, illumination source 124 may be camera flashes or the like, and the light 132 generated by the illumination source 124 may be light that provides a high contrast, such as white light. The light 132 generated by the illumination source 124 may have a ring shape, a spotlight shape, or other shape. By directing the light 132 to an area beneath the platen 118, the wafer 108 will appear backlit to the imaging device 122, thus increasing visual contrast at a perimeter 134 of the wafer 108. Furthermore, this position of the light 132, below the platen 118, minimizes difficulties due to reflection from the wafer 108 and surfaces of the processing chamber 116, and is more reliable compared to front/top lighting and image processing. It will be appreciated that the illumination source 124 may vary, and that the wavelength of the light may be optimized, e.g., by moving more into the ultra-violet or into the near infrared, in the case of transparent substrates to improve the edge shadow definition.

In the embodiment shown, the imaging device 122 may be a camera positioned perpendicular to a top surface of the wafer 108. The imaging device 122 may be positioned external to the processing chamber 116, adjacent a window 136.

As further shown, within the processing chamber 116 may be the rotating platform 140 including a base 141 coupled to one or more outwardly extending side arms 142, spaced apart from one another. The rotating platform 140 may support and control the platen 118, which may be an electrostatic chuck capable of clamping the wafer 108 in place through the use of electrostatic force. One or more motors (not shown) may be disposed within the rotatable platform 140 to allow the platen 118 to rotate/spin around an axis perpendicular to the plane of the platen 118, passing through the center of the platen 118. During use, the rotating platform 140, the illumination source 124, and the imaging device 122 may be operated by one or more controllers 144.

The rotating platform 140 further allows rotation of the platen 118 around a second axis horizontal to the plane of the platen 118, and oriented perpendicular to the first axis. The rotating platform 140 may be capable of at least 90° of rotation. For example, the rotating platform 140 has a first position known as the load/unload position, where the rotating platform 140 is oriented so the platen 118 is horizontal or approximately horizontal. While in this load/unload position, the wafer 108 may be placed on the platen 118, and, after processing, subsequently may be removed from the platen 118.

The rotating platform 140 also has a second position, known as the operational position, where the rotating platform 140 is oriented so the platen 118 is vertical or approximately vertical. In this operational position, the platen 118 and the clamped wafer 108 are facing the ion beam being directed toward the platen 118. In other words, a plane formed by a surface of the platen 118.

Control of the rotating platform 140, the illumination source 124, and the imaging device 122 may be performed by the controller 144 operably connected therewith. More specifically, the processing of the signals from the imagining device 122, the processing and storage of data and the communication of signals to and from the rotating platform 140, is undertaken by the data processing and a control module of the controller 144. Although non-limiting, controller 144 may include a Field Processing Gate Array (FPGA) which is programmed to control the operation of the imaging device 122 and the illumination source 124, process the pixel signals from the imaging device 122, analyze as required the individual pixel data, retrieve and store data in memory 147, and receive and send signals via a wired or wireless communication module. In other embodiments, the controller 144 may additionally or alternatively include a microprocessor, digital signal processor (DSP), or a uniquely designed application specific integrated circuit (ASIC).

The memory 147 may include non-volatile memory for storing key data such as, and not limited to, position data for the platen 118, position data for the wafer 108, position data for the alignment mark 150, and other parameters required for the operation of the system 100. An alternative implementation could utilize dynamic random access memory (DRAM).

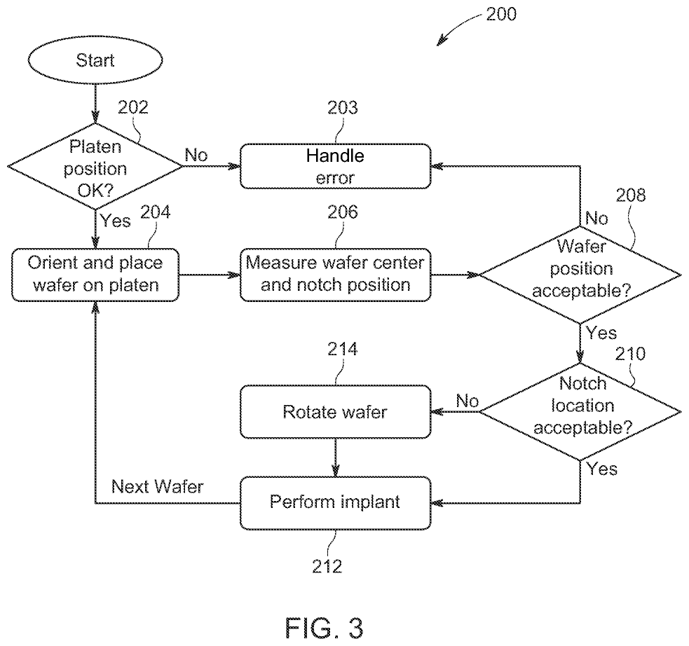

With reference to FIGS. 2-3, one non-limiting process 200 for in-situ verification and correction of the position of the wafer 108 will be described. At block 202, it is determined whether the position of the platen 118 is acceptable. Additionally, the position of the platen 118 relative to the imaging device 122 is determined to establish a reference against which wafers subsequently positioned atop the platen 118 will be measured. In some embodiments, determining the position of the platen 118 may include detecting, using the imaging device 122, an outer perimeter of the platen 118 after the illumination source 124 has been activated. In other embodiments, the imaging device 122 may recognize one or more other visual features of the platen 118, such as a pre-marked center point.

In some embodiments, a calibration routine may be run whereby the controller 144 instructs the imagining device 122 to take one or more images of the platen 118 edge when the platen 118 is in an initial position. Firmware in the controller 144 compares each pixel's bit count for light intensity to determine if the pixel is obscured by the platen 118 or not. The firmware in the controller 144 may then determine position data for the platen, such as coordinates corresponding to the platen 118 edge by determining the last fully obscured pixels in the first and last column of a pixel array. Partially obscured pixels may also be detected, wherein the ability to extrapolate dimensions based upon fractional levels of light in a pixel enables greater accuracy.

Once the dimensions for the intersections of the edge of the platen 118 are determined, the firmware uses these values to determine the absolute calibration distances from the imaging device 122, and to determine a reference center point for the platen 118. The reference/calibration dimensions are then stored in memory 147 and used as reference data to post verify the position of the wafer 108. The reference/calibration dimensions may also be compared against previously stored values (i.e., an expected platen position) to determine if an unacceptable deviation exists. If the position of the platen 118 is not acceptable (i.e., ‘NO), then the process 200 moves to block 203, and a handle error is issued. If YES, the position of the platen 118 is acceptable, the process moves to block 204.

At block 204, the wafer 108 is then oriented and placed on the platen 118. Ideally, the center of the wafer 108 is aligned with, and placed directly over, the determined center of the platen 118. Furthermore, the alignment mark 150 may be initially aligned with an expected notch position, which is stored within memory 147. In some embodiments, the alignment mark 150 may be formed in a sidewall of the wafer 108, and may be a variety of shapes, e.g., triangular, rectangular, a round, etc. Although non-limiting, the alignment mark 150 may have a width ranging from about 1 mm to about 4 mm and a depth from a sidewall of the wafer 108 ranging from about 1 mm to about 4 mm. As such, the alignment mark 150 may be easily detectable, without overly limiting the area of the wafer 108 occupied by the alignment mark 150. In some embodiments, the alignment mark 150 may be a reflective alignment mark, a high-contrast alignment mark, or the like.

At block 206, once the wafer 108 is in place, an actual wafer center and position of the alignment mark 150 (e.g., notch) are determined. That is, the controller 144 instructs the imagining device 122 to take one or more images of the wafer 108 to determine the perimeter 134 thereof. The firmware in the controller 144 may then determine the coordinates corresponding to the perimeter 134, and use the perimeter 134 coordinates to determine the center point for the wafer 108. In some embodiments, the coordinates and center point for the wafer 108 are calculated relative to the previously determined absolute calibration distances from the imaging device 122 and the platen coordinates established when imaging the platen 118.

It will be appreciated that the wafer 108 may be loaded on the platen 118 with x-direction and y-direction misalignments between the center point of the wafer 108 and the center point of the platen 118. At block 208 it is therefore determined whether the wafer 108 alignment is acceptable within a predetermined limit. In some embodiments, the center point of the wafer 108 is compared to the center point of the platen 118 to determine misalignment, if any, in the x-direction and y-direction. If the misalignment exceeds a predetermined limit, the wafer position is considered unacceptable (i.e., ‘NO’), and the process 200 indicates a handle error. If YES, the process 200 proceeds to block 210 to determine if the position of the alignment mark 150 is acceptable.

In some embodiments, the imagining device 122 sends visual data to the controller 144 to determine the position of the alignment mark 150 and/or any other identifying features on the surface of the wafer 108. Based on the position of the alignment mark 150, the rotational position of the wafer 108 may be determined. The rotational misalignment of the wafer 108, if present, may then be calculated based on the rotational position of the wafer 108 as compared to the expected notch position stored in memory 147. If the notch location is acceptable, then the process 200 proceeds to block 212 where the wafer 108 receives an ion treatment. However, if the notch location is unacceptable, the process 200 proceeds to block 214, wherein the rotating platform 140 adjusts the rotation of the platen 118 and the wafer 108 in order to correct for the rotational misalignment. Once rotated, the ion exposure process may be performed. Correcting the misalignments between the wafer 108 and the platen 118 prior to exposing the wafer 108 to the ion beam improves the uniformity of the ion exposure process across the surface of the wafer 108, reduces wafer-to-wafer process variations, reduces device defects, and improves device performance. In various embodiments, the ion exposure process may be any suitable process, such as an ion etching process, an ion implantation process, or the like. The ion beam may be generated by an ion beam generator, which may include any number of an ion source, a mass analysis magnet, an aperture, a linear accelerator, a scanning unit, a converging unit, a final energy magnet, an end station, and/or the controller 144.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

1. A method, comprising:
illuminating an underside of a platen positioned within a chamber;
detecting a perimeter edge of the platen using an imaging device positioned external to the chamber;
determining, via a controller, position data for the platen based on the detected perimeter edge of the platen;
positioning a wafer atop the platen based on the position data of the platen, wherein the wafer comprises a positioning notch;
detecting a position of the wafer and a position of the positioning notch using the imaging device; and
comparing the position data of the platen to the detected position of the wafer.

2. The method of claim 1, further comprising determining whether to proceed to an implant process based on a comparison of the detected position of the platen to an expected reference position of the platen.

3. The method of claim 1, further comprising comparing the position of the positioning notch to an expected notch position.

4. The method of claim 3, further comprising rotating the platen to align the positioning notch with the expected notch position.

5. The method of claim 4, wherein the platen is rotated when the platen moves to an implant position.

6. The method of claim 3, further comprising determining whether to proceed to an implant process based on the comparison of the detected position of the wafer to the position data of the platen, and based on the comparison of the position of the positioning notch to the expected notch position.

7. The method of claim 1, further comprising positioning an illumination source beneath the platen, wherein detecting the position of the wafer comprises detecting a center point of the platen based on the detected perimeter edge, and wherein positioning the wafer atop the platen further comprises aligning a center point of the wafer with the center point of the platen.

8. (canceled)

8. A system for in-situ verification and correction of wafer position, the system comprising:
an illumination device operable to illuminate an underside of a platen, wherein the platen is positioned within a chamber, wherein the illumination device is positioned external to the chamber, and wherein the illumination device is operable to:
detect a perimeter edge of the platen;
detect a perimeter edge of a wafer positioned atop the platen and a position of a positioning notch formed in the wafer;
a controller in communication with the illumination device and the platen, wherein the controller is operable to:
determine position data for the platen based on the detected perimeter edge of the platen;
determine a position of the wafer and a position of the positioning notch; and
compare the position of the wafer to the position data of the platen and compare the position of the positioning notch to an expected notch position.

9. The system of claim 8, wherein the controller is further operable to rotate the platen to align the positioning notch with the expected notch position.

10. The system of claim 9, wherein the controller is further operable to rotate the platen when the platen moves to an implant position.

11. The system of claim 8, wherein the controller is further operable to determine whether to proceed to an implant process based on the comparison of the detected position of the wafer to the position data of the platen.

12. The system of claim 8, wherein the controller is further operable to determine whether to proceed to an implant process based on a comparison of the detected position of the platen to an expected reference position of the platen.

13. The system of claim 8, wherein the controller is further operable detect a center point of the platen based on the detected perimeter edge, and wherein the wafer is positioned atop the platen by aligning a center point of the wafer with the center point of the platen.

14. A method of in-situ verification and correction of wafer position, the method comprising:
illuminating an underside of a platen positioned within a processing chamber;
detecting a perimeter edge of the platen using an imaging device positioned external to the processing chamber, above the platen;
determining, via a controller, position data for the platen based on the detected perimeter edge of the platen;
positioning a wafer atop the platen based on the position data of the platen, wherein the wafer comprises a positioning notch;
detecting a position of the wafer and a position of the positioning notch using the imaging device; and
comparing the position data of the platen to the detected position of the wafer.

15. The method of claim 14, further comprising comparing the position of the positioning notch to an expected notch position.

16. The method of claim 15, further comprising rotating the platen to align the positioning notch with the expected notch position.

17. The method of claim 16, wherein the platen is rotated when the platen moves to an implant position.

18. The method of claim 15, further comprising determining whether to proceed to an implant process based on each of the following: a comparison of the detected position of the platen to an expected reference position of the platen, the comparison of the detected position of the wafer to the position data of the platen, and the comparison of the position of the positioning notch to the expected notch position.

19. The method of claim 14, further comprising positioning an illumination source beneath the platen.

20. The method of claim 14, further comprising detecting a center point of the platen based on the detected perimeter edge, wherein positioning the wafer atop the platen further comprises aligning a center point of the wafer with the center point of the platen.
